(19) United States
(12) Patent Application Publication
(10) Pub. No.: US 2012/0288762 A1
(43) Pub. Date: Nov. 15, 2012

(54) GRAPHENE-COATED PYROLYTIC CARBON STRUCTURES, METHODS OF MAKING, AND METHODS OF USE THEREOF

(75) Inventors: Ian R. Hardin, Athens, GA (US); Ming Zhang, Ganinesville, FL (US)

(73) Assignee: UNIVERSITY OF GEORGIA RESEARCH FOUNDATION, INC., Athens, GA (US)

(21) Appl. No.: 13/461,190

(22) Filed: May 1, 2012

Related U.S. Application Data
(60) Provisional application No. 61/484,286, filed on May 10, 2011.

(51) Int. Cl. C09D 1/00; B32B 9/00; B32B 5/02; H01M 4/60; B05D 3/02; H05K 9/00; B01J 21/18; H01B 1/04; B82Y 40/00; B82Y 30/00

(52) U.S. Cl. 429/213; 502/180; 428/408; 428/368; 442/111; 428/336; 428/76; 427/372.2; 174/350; 977/734; 977/932

(57) ABSTRACT

Embodiments of the present disclosure provide for flexible graphene-coated pyrolytic carbon materials or structures, methods of making, methods of use, materials including the graphene-coated pyrolytic carbon material or structure, structures including the graphene-coated pyrolytic carbon material or structure, and the like.

### CROSS-REFERENCE TO RELATED APPLICATION

This application claims priority to U.S. provisional application entitled “GRAPHENE-COATED PYROLYTIC CARBON STRUCTURE, METHODS OF MAKING, AND METHODS OF USE THEREOF,” having Ser. No. 61/484,286, filed on May 10, 2011, which is entirely incorporated herein by reference.

### BACKGROUND

Recently, great interest has been focused on graphene nanocomposites for a variety of applications. Graphene is a one atom-thick material made up of sp²-bonded carbon atoms. Its unique properties include high electrical and thermal conductivity, the quantum Hall effect, massless transportation properties, and strong mechanical properties. Among several possible applications, the use of graphene as an electrode in lithium batteries is very promising because of graphene's relatively low-cost and accessibility.

### SUMMARY

Embodiments of the present disclosure provide for flexible graphene-coated pyrolytic carbon materials or structures, methods of making, methods of use, materials including the graphene-coated pyrolytic carbon material or structure, structures including the graphene-coated pyrolytic carbon material or structure, and the like.

An embodiment of the present disclosure includes a structure, among others, that includes: a graphene-coated pyrolytic carbon (GCPC) structure. In an embodiment, the GCPC structure includes a graphene-coated pyrolytic carbon layer around a fiber or a fabric. In an embodiment, the fiber or a fabric is a cotton fiber or fabric.

An embodiment of the present disclosure includes a method of making a structure, among others, that includes: disposing a fiber or a fabric into a graphene/pyrene derivative suspension to coat the fiber or the fabric; and annealing the coated fabric, where a graphene-coated pyrolytic carbon layer is formed around the fiber or fabric. In an embodiment, the layer is a graphene skin on a pyrolytic carbon scaffold. An embodiment of the present disclosure includes a structure formed by this process.

An embodiment of the present disclosure includes a device, among others, that includes: a graphene-coated pyrolytic carbon (GCPC) structure. In an embodiment, the device includes an anode, a lithium battery, a flexible electronic device, an anti-static material, an electromagnetic shield, an electrode, a heating element in a textile and in apparel, a sensor, a radio-interference prevention shield, a wearable electronic device, a parabolic antenna reflecting materials, a catalyst, or a biomedical implant.

### BRIEF DESCRIPTION OF THE DRAWINGS

Many aspects of the disclosed devices and methods can be better understood with reference to the following drawings. The components in the drawings are not necessarily to scale, emphasis instead being placed upon clearly illustrating the relevant principles. Moreover, in the drawings, like reference numerals designate corresponding parts throughout the several views.

FIG. 1A illustrates an atomic force microscopy (AFM) image of the graphene sheets on a mica substrate. FIG. 1B illustrates is a section analysis of the AFM image in FIG. 1A along the black line. The arrows in the pictures help to show the height of the graphene sheet. FIG. 1C is scheme 1 that is an illustration of the mechanism of the intermolecular condensation of graphene and pyrene into graphene networks on the surface of a fiber.

FIG. 2 illustrates a fluorescence spectroscopy used to monitor the direct exfoliation process in the presence of pyrene molecules.

FIG. 3A illustrates an incomplete light-emitting diode; FIGS. 3B and C illustrate a light-emitting diode circuit closed by cotton/graphene hybrids or graphene-coated pyrolytic carbon; FIG. 3D illustrates a photograph of graphene-coated pyrolytic carbon; and FIG. 3E illustrates graphene-coated pyrolitic carbon stretched by tweezers.

FIGS. 4A and 4B illustrate SEM morphological structures of graphene-coated pyrolytic carbon. FIGS. 4C and 4D illustrate SEM cross sections of a broken graphene-coated pyrolytic carbon.

FIG. 5 is a graph that illustrates EDX analysis of the surface of a graphene-coated pyrolytic carbon anode sample.

FIG. 6 is a graph that illustrates the cycleability of graphene-coated textile at 50 mA g⁻¹ current density.

### DETAILED DESCRIPTION

Before the present disclosure is described in greater detail, it is to be understood that this disclosure is not limited to particular embodiments described, as such may, of course, vary. It is also to be understood that the terminology used herein is for the purpose of describing particular embodiments only, and is not intended to be limiting, since the scope of the present disclosure will be limited only by the appended claims.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, the preferred methods and materials are now described.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present disclosure is not entitled to antedate such publication by virtue of prior disclosure. Further, the dates of publication provided could be different from the actual publication dates that may need to be independently confirmed. Terms defined in references that are incorporated by reference do not alter definitions of terms defined in the present disclosure or should such terms be used to define terms in the present disclosure they should only be used in a manner that is inconsistent with the present disclosure.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

Embodiments of the present disclosure will employ, unless otherwise indicated, techniques of chemistry, inorganic chemistry, material science, and the like, which are within the skill of the art. Such techniques are explained fully in the literature.

The following examples are put forth so as to provide those of ordinary skill in the art with a complete disclosure and description of how to perform the methods and use the compositions and compounds disclosed and claimed herein. Efforts have been made to ensure accuracy with respect to numbers (e.g., amounts, temperature, etc.), but some errors and deviations should be accounted for. Unless indicated otherwise, parts are parts by weight, temperature is in ° C., and pressure is in atmosphere. Standard temperature and pressure are defined as 25° C. and 1 atmosphere.

Before the embodiments of the present disclosure are described in detail, it is to be understood that, unless otherwise indicated, the present disclosure is not limited to particular materials, reagents, reaction materials, manufacturing processes, or the like, as such can vary. It is also to be understood that the terminology used herein is for purposes of describing particular embodiments only, and is not intended to be limiting. It is also possible in the present disclosure that steps can be executed in different sequence where this is logically possible.

It must be noted that, as used in the specification and the appended claims, the singular forms “a,” “an,” and “the” include plural referents unless the context clearly dictates otherwise. Thus, for example, reference to “a support” includes a plurality of supports. In this specification and in the claims that follow, reference will be made to a number of terms that shall be defined to have the following meanings unless a contrary intention is apparent.

### Definitions

As used herein, the term “fiber” refers to filamentous material that can be used in fabric and yarn as well as textile fabrication. One or more fibers can be used to produce a fabric or yarn. Fibers can include, without limitation, materials such as cellulose, fibers of animal origin (e.g., alpaca, angora, wool and vicuna), hemicellulose, lignin, polyesters, polyamides, rayon, modacrylic, aramids, polyacetates, polyxanthates, acrylics and acrylonitriles, polyvinyls and functionalized derivatives, polyvinylidenes, polyfluoroethylene, PTFE, latex, polystyrene-butadiene, polyethylene, polyacetylene, polycarbonates, polyethers and derivatives, polyurethane-polyurea copolymers, polybenzimidazoles, silk, lyocell, carbon fibers, polyphenylene sulfides, polypropylene, polylactides, polyglycolids, cellophane, polycaprolactone, “M5” (poly{diimidazo pyridinylene (dihydroxy) phenylene}), melamine-formadehyde, plastarch, PPOs (e.g., Zylon®), polyolefins, and polyurethane. In an embodiment, the fiber is made of cotton. In an embodiment, the fiber can have a diameter of about 200±100 nanometers, in the case of nanofibers, to about 1 to 40 microns in the case of conventional fibers, and a length of about ½ inch to 5 inches in the case of staple fibers, but in an embodiment, the fibers can also be continuous filament fibers. One or more fibers can be used to produce a fabric or yarn, where the fibers can be the same type (e.g., cotton fibers) or different types (e.g., cotton fibers, wool fibers, and the like).

The term “textile article” can include garments, fabrics, carpets, apparel, furniture coverings, drapes, upholstery, bedding, automotive seat covers, fishing nets, rope, articles including fibers (e.g., natural fibers, synthetic fibers, and combinations thereof), articles including yarn (e.g., natural fibers, synthetic fibers, and combinations thereof), and the like. In an embodiment, the textile article can be made of different types of fibers (e.g., cotton fibers, wool fibers, and the like) or can be made of one type of fiber (e.g., cotton fibers).

### Discussion

Embodiments of the present disclosure provide for flexible graphene-coated pyrolytic carbon materials or structures, methods of making, methods of use, materials including the graphene-coated pyrolytic carbon material or structure, structures including the graphene-coated pyrolytic carbon material or structure, and the like.

Embodiments of the present disclosure can use a fiber, fibers, or a fabric that can be made into the graphene-coated pyrolytic carbon (GCPC) structure. In an embodiment, GCPC structure includes a fiber, fibers, or a fabric that has a graphene-coated pyrolytic carbon layer disposed on the fiber(s). In an embodiment, the graphene-coated pyrolytic carbon layer can be formed around (e.g., completely or substantially (e.g., about 50% or more, about 60% or more, about 70% or more, about 80% or more, about 90% or more, about 95% or more, or 99% or more)) the fiber, each of the fibers, or the fabric. In an embodiment, the graphene-coated pyrolytic carbon layer can be about 0.335 nanometers to 1 micrometer thick.

In an embodiment, the pyrolytic carbon structure with the graphene-coated pyrolytic carbon layer is formed from a fiber, fibers, or a textile fabric. In an embodiment, graphene segments are caused to be attached to one another (e.g., chemically welded) to surround the surface(s) of the fiber, fibers, or the textile fabric using pyrenesulfonictetrasodium salt hydrate (PPTSA), or a combination thereof.

In an embodiment, the graphene segments can have a thickness of about 0.3 nanometers (e.g., about 0.335 nm), for a single graphene segment, to 1 micrometer, if more than one graphene segment is present. In an embodiment, graphene segments can have a length of about 200 nanometers to 10 micrometers. In an embodiment, graphene segments can have a width of about 200 nanometers to 10 micrometers.

In an embodiment, the starting materials, the fiber, fibers, or textile fabrics, are dipped into a dispersion of graphene sheets and PYTSA in water. In an embodiment, the ratio of the graphene sheets to PYTSA can be about 5-1 to 100-1. In an embodiment, the fiber, fibers, or textile fabrics are then annealed at high temperature (e.g., about 600 to 1000° C.), causing the PYTSA molecules to become incorporated into a sheet of graphene that is wrapped around the fiber, fibers, or fibers in the fabric. The resulting graphene-coated pyrolytic carbon (GCPC) structure shows good flexibility and excellent electrical conductivity (e.g., a low resistance of about 32 to 100 ohms) and a charge/discharge performance of about 300 mAh g⁻¹±75 maintained over fifty charge/discharge cycles.

In an embodiment, the GCPC material can be used as anodes in lithium batteries, at a much lower cost than the use of carbon nanotubes for that purpose. One advantage is that the charge-discharge performance of the GCPC material is superior to carbon anodes now being used in lithium batteries.

Other potential uses of these GCPC materials include the following: flexible and wearable electronics, anti-static materials, electromagnetic shielding, electrodes, heating elements in textiles and apparel, sensors (pressure, biomechanical monitoring, biosensors), changing thermal conductivity and moisture transport, radio-interference prevention shields, wearable electronic devices, parabolic antenna reflecting materials, catalysts, biomedical applications (blood clot resistance in implants).

### EXAMPLE

Now having described the embodiments of the disclosure, in general, the examples describe some additional embodiments. While embodiments of the present disclosure are described in connection with the example and the corresponding text and figures, there is no intent to limit embodiments of the disclosure to these descriptions. On the contrary, the intent is to cover all alternatives, modifications, and equivalents included within the spirit and scope of embodiments of the present disclosure.

### Example

### Brief Introduction

In this Example, we utilized cotton fabric as a template to create macro sheets of graphene. The cotton fabric was dipped into a graphene/pyrene-derivative suspension. The graphene-coated cotton textile was then annealed at a high temperature in a quartz tube furnace under argon flow. During the annealing process, the gaps between separated graphene sheets were “soldered” by the “glue” molecules (aromatic molecular surfactants) to form graphene-coated pyrolytic carbon. The result was a graphene “skin” created on the pyrolytic carbon scaffold that is flexible graphene coat and can contribute relatively high capacity to a lithium battery sandwich. This occurs because of porous structure of graphene sheets and the high surface area of the pyrolyzed carbon with a shell-core structure. This novel, facile, and low-cost method can be expanded to applications on other carbon-rich materials such as peanut shells, wood waste and other cellulosic waste materials.

### Introduction

Recently, great interest has been focused on graphene nanocomposites for various applications. Graphene is a one atom-thick material made up of sp²-bonded carbon atoms. Its unique properties include high electrical and thermal conductivity, the quantum Hall effect, massless transportation properties, and strong mechanical properties [1-11]. Among several possible applications, the use of graphene as an electrode in lithium batteries is very promising because of graphene's relatively low-cost and accessibility. However, a graphene anode alone provides relatively low lithium storage capacity and has an unstable charge and discharge cycle performance, which is a problem to overcome before the commercialization of graphene based electrodes is feasible. Recently, several different nanomaterials, including various carbonaceous materials and nanometal/oxides, have been tested as templates to enhance the lithium storage capacity and the cycling performance of the graphene [12-14]. However, because of the high cost, inaccessibility, and the potential nano-toxicity of these template materials, it has been difficult to produce graphene-based electrode materials on a large scale.

Cotton is almost pure cellulose. It is a carbon-rich, cheap, and available on a large scale. Recently, Cui et al reported that highly electroconductive cotton/carbon nanotube composites can be simply prepared by dipping a cotton fleece (pile) fabric in a carbon nanotube solution. This was successful because of the flexibility of the nanotubes and the strong binding between the carbon nanotubes and the cotton fibers [15-16]. Graphene also exhibits the good flexibility and electro-conductivity that carbon nanotubes do, but with the added advantage of being potentially much less expensive.

However, little research has been done on the fabrication of graphene-coated textiles, probably due to the difficulty of preparing stable graphene solutions, wrapping the seamless graphene layer on the fibers, and reaggregation of graphene sheets, as well as the complications of pre- and post-treatments. Mullen et al reported that pyrene molecules can not only act as nano-graphene molecules to heal possible defects in the graphene oxides, but can function as electrical “glue”, soldering adjacent graphene sheets during the annealing process [17]. In addition, He and colleagues reported a simple and scalable exfoliation approach to produce high-quality graphene suspensions by sonicating graphite in an aqueous solution of hydrophilic pyrene molecules [18]. In the present work (as shown in Scheme 1), we use cotton fibers as templates where the graphene sheets are created and wrapped around the fibers. This is done by dipping the cotton fleece fabric in a graphene suspension and “soldering” with the nanographene (pyrene derivative) by annealing. The result is a graphene-coated pyrolytic carbon material. Here, the pyrene derivative plays a double role in the preparation of the material. In the graphene suspension, the pyrene derivative acts as a surfactant to disperse, stabilize, and separate the graphite sheets from each other; in the annealing process, it acts as a “glue” to heal defects and bridge the gap between graphene sheets. Because of the core-shell structure of the graphene-coated pyrolytic carbon, we believe that the graphene-coated pyrolytic carbon will exhibit excellent charge/discharge performance, as well as mechanical flexibility.

In the present example, the chemical nature, morphology, and thermal and electrical properties of the graphene-coated textile nanocomposites have been studied by atomic force microscopy (AFM), UV-Vis spectroscopy, scanning electron microscopy (SEM), energy-dispersive X-ray spectroscopy (EDS) and galvanostatic charge-discharge experiments. The primary goal of this work is to produce a facile, low-cost method to prepare graphene-coated pyrolytic carbon materials for potential applications in energy-storage, electronics, “smart” textiles and perhaps in water treatment.

### Experimental Section

### Materials

Synthetic graphite powder (<20 mm particle size), and 1, 3, 6, 8-pyrenetetrasulfonic acid (Py-SO₃) tetrasodium salt hydrate from Sigma-Aldrich were purchased and used as received. The cotton fleece fabric (390 g/m²) was produced in the labs of Cotton Inc., Cary, N.C.

### Preparation of the Graphene Suspension

A graphene suspension was synthesized from natural graphite flakes by a method similar to that described by He et al [18]. A stock solution of Py-SO₃ with a concentration of 0.5 mg/mL. was prepared in deionized water by vigorous stirring for 1 hour. Graphite powder was added to the resultant solutions with the weight ratio between the pyrene derivatives to the graphite powder of 2:1. Direct exfoliation of graphite to graphene sheets was performed by bath sonication of the obtained mixture solutions for 1 hour. The exfoliation process was monitored by monitoring the fluorescence ultraviolet-visible absorption spectrum at the beginning and end of the exfoliation period. The obtained grey suspension was used directly to prepare a graphene coated textile by annealing.

### Preparation of Graphene-Coated Pyrolytic Carbon

Graphene sheets were produced on cotton fabric by using a method similar to that described by Cui et al [15] to coat cotton fibers with carbon nanotubes. Herein, a piece of the cotton fleece was dipped into the prepared graphene suspension. The fabric was then dried at 80° C. for two hours. A piece of the coated fabric was then cut—7 cm length and 4 cm width—and then annealed for 20 minutes at 700° C. under inert gas (argon) flow.

### Characterization

The sonicated dispersion of exfoliated graphene sheets was pipetted onto a mica sheet and dried. These sheets were then imaged with a tapping mode Nanoscope IIIa atomic force microscopy (AFM) instrument (Veeco instrument, Santa Barbara, Calif., USA). The fluorescence spectrum of the graphite dispersion in Py-SO₃ was monitored using a Cary-Eclipse fluorescence spectrophotometer (Varian, Inc, Palo Alto, Calif.). The morphology, microstructures and EDX analysis of the graphene-coated pyrolytic carbon were characterized using a field emission gun scanning electron microscope (Philips XL-30). Electrochemical charge/discharge performance of the graphene-coated pyrolytic carbon was evaluated using 2032 button coin cells (Hohsen Corp.)[19]. The coin cells were assembled in a high purity argon filled glove box. Charge (lithium insertion) and discharge (lithium extraction) were conducted using an Arbin automatic battery cycler at a constant current density of 50 mA g⁻¹ between cut-off potentials of 0.01 and 2.8 V.

### Results and Discussion

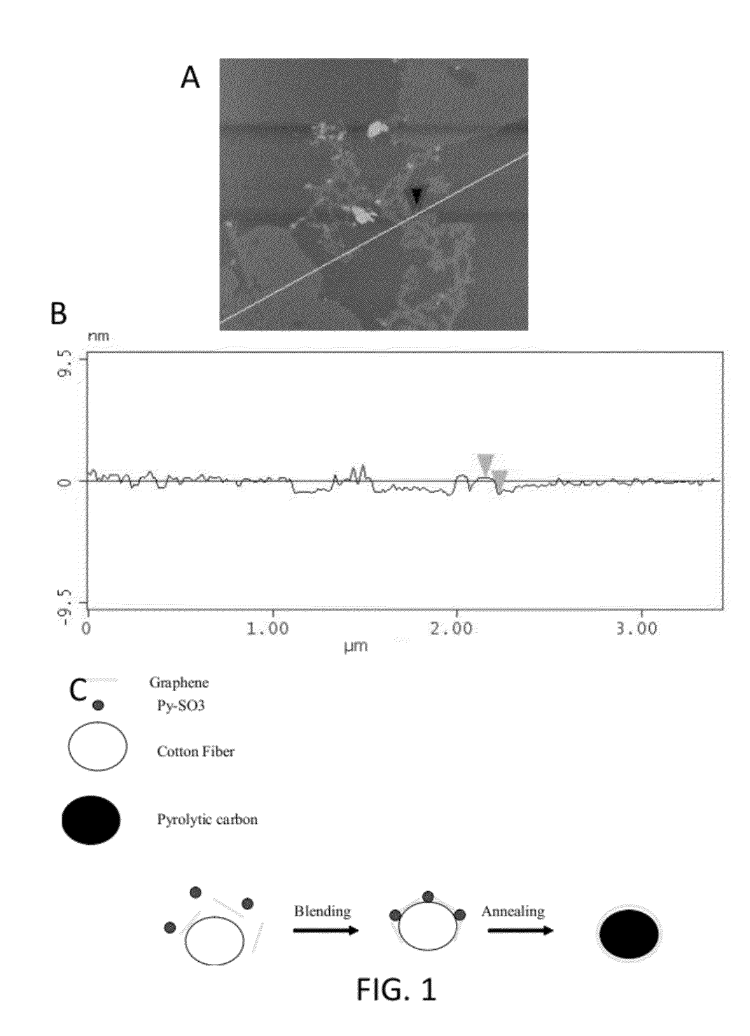

Atomic force microscopy (AFM) was used to characterize the graphene sheets obtained by sonication in aqueous solution. FIG. 1A illustrates a typical tapping-mode AFM image of graphene/pyrene hybrids deposited on a freshly cleaved mica surface. The size of the graphene patches were in the micrometer range. The thickness of a single-layer hybrid ranged from 0.5 to 1.3 nm with an average of 0.9±0.4 nm, measured from cross-sectional images, as shown in FIG. 1B. The variation in the thicknesses was attributed to the possible inhomogeneous coverage of Py-SO3 molecules on the graphene surface, or simply due to the AFM system noise [18]. There were some holes in the surfaces with diameters ranging from 2 nm to 500 nm randomly arranged on the graphene sheets. We believe that these holes were caused by sonication and can be partly healed during annealing and facilitate capture of Li-ions.

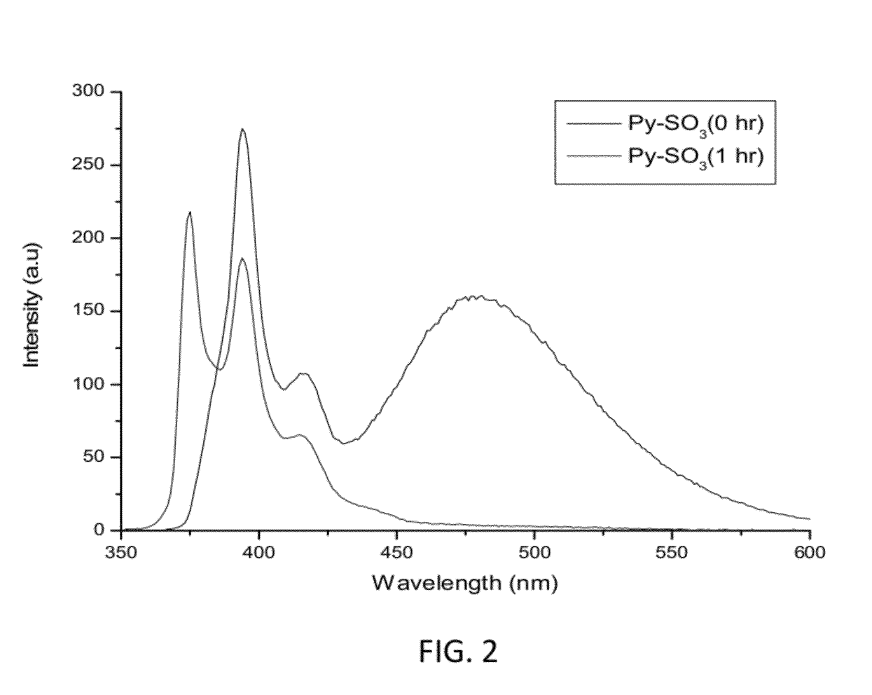

FIG. 2 shows the fluorescence spectra (excited at 340 nm) of a graphene/pyrene suspension for different sonication periods. Prior to sonication, the spectrum shows a large peak at 500 nm, which was ascribed to the excimer emission of pyrene derivatives [20, 21]. We found that the intensity of this peak decreased significantly after one hour of sonication. At the same time, we observed a dramatic increase in the peak at 374 nm. This fluorescence behavior is virtually the same as that of the pyrene aqueous solutions alone when the concentration of pyrene is below its critical micelle concentration, suggesting that the fluorescence of the graphene/pyrene solution is derived by the non-bound (free) pyrene monomers in the solution. FIGS. 1 and 2 indicate that the graphene suspension was successfully synthesized by sonication in pyrene aqueous solution.

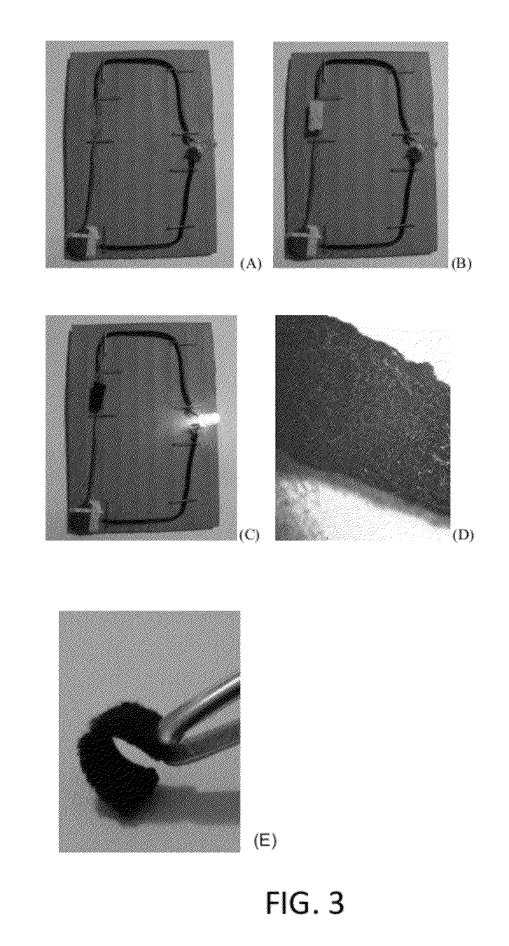

FIGS. 3(A) and 3(B) shows the pictures of the graphene-coated pyrolytic carbon sample, which is flexible and metallic. FIGS. 3(C)-(E) shows a circuit designed to test the conductivity of graphene-coated pyrolytic carbon samples before and after annealing. The figure shows that annealing improves the conductivity of the sample, which allows the successful operation of the light-emitting diode in the circuit.

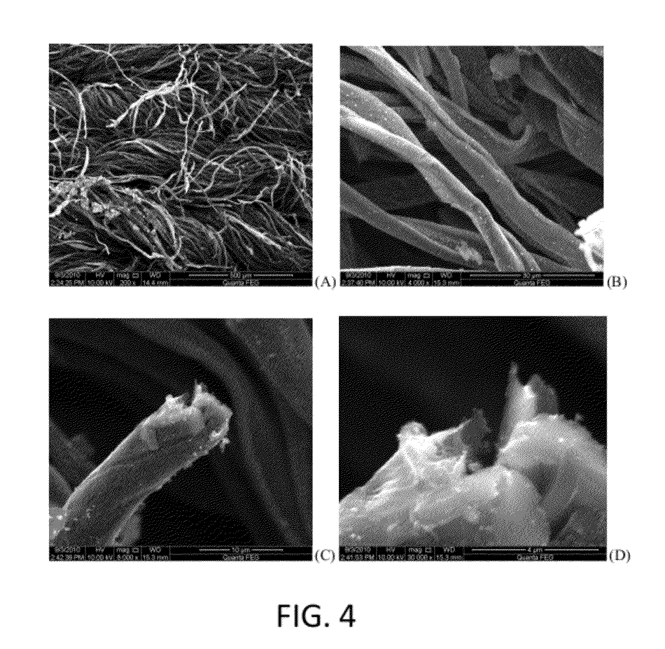

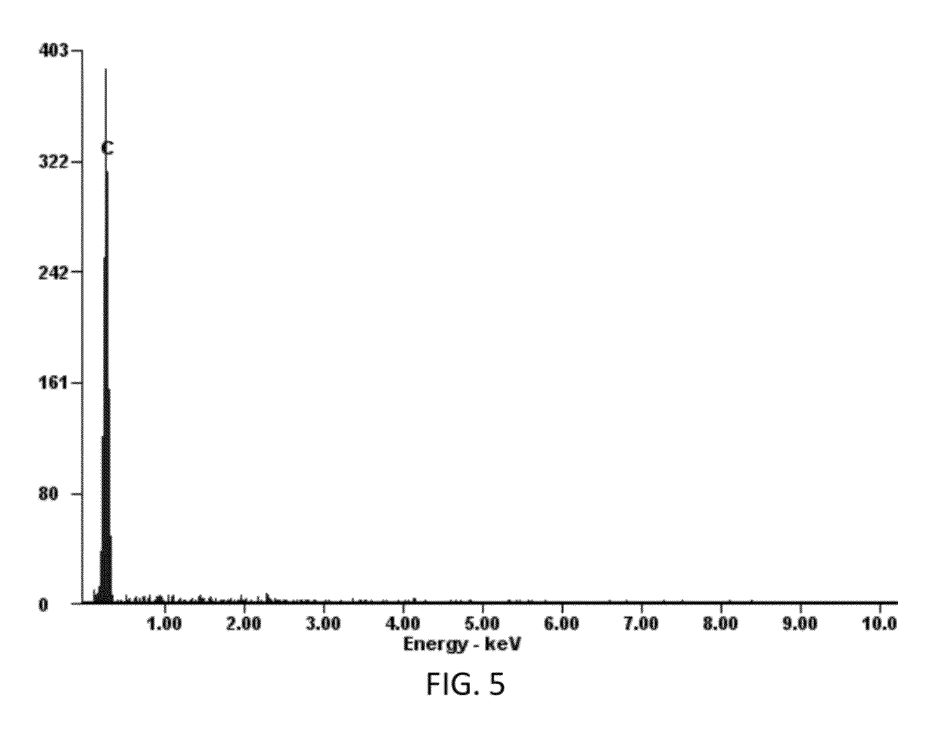

FIG. 4 shows an SEM image of the graphene-coated pyrolytic carbon after annealing. FIGS. 4A and 4B show that the graphene sheets grew up on the fibers uniformly and smoothly and that the fibers kept the original morphological structure. This indicates that pyrene molecules are successful in “gluing” the graphene sheets to form a seamless membrane on the surface of the fibers during annealing. FIGS. 4C and 4D show the cross-section of a broken fiber where the graphene sheets can be seen on the circumference of the cross-section. In FIG. 5, EDX data indicate that almost 100 percent of the elements are on the surface of the observed fibers are carbon, which means that the oxygen containing groups in the graphene sheet and the Py-SO₃ have almost completely disappeared. This further demonstrates that the graphene sheets are ‘soldered’ by the fusion of graphene sheets and Py-SO₃ on the fiber surfaces.

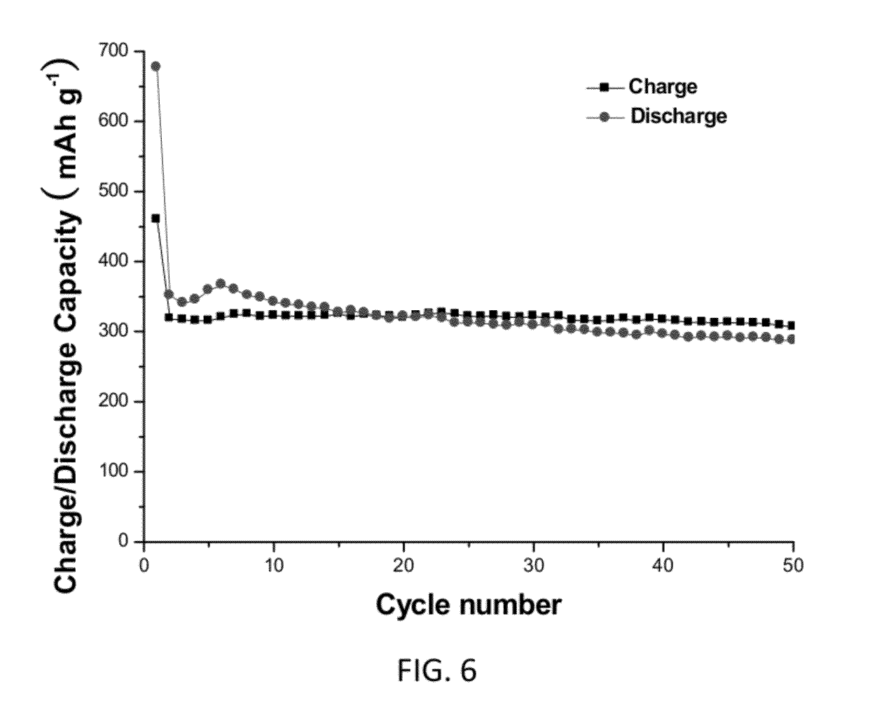

Galvanostatic charge-discharge experiments were carried out at a current density of 50 mA g⁻¹ within a voltage window of 0.01-2.8 V to evaluate the electrochemical performance of graphene-coated pyrolytic carbon anodes (FIG. 6). The figure shows that graphene-coated pyrolytic carbon anodes have larger lithium storage capacities than graphene paper anodes normally used in lithium batteries. For the latter, the discharge capacity drops sharply from 680 mA h g⁻¹ to 84 mA h g⁻¹ from the first to the second cycle [22]. For the graphene-coated pyrolytic carbon anodes, about 50 percent of capacity loss was observed in the first cycle, after which the charge-discharge efficiency was above ˜94 percent from the 2^{nd} cycle to the 50^{th} cycle (FIG. 6). Notably, the graphene-coated pyrolytic carbon electrode provided a reversible discharge capacity as high as 288 mAh g−1 (82.1% of the capacity on the second cycle) even after 50 cycles, whereas with the pyrolytic carbon electrode alone rapid degradation occurred.

We believe that the remarkable high electrochemical performance of the graphene-coated pyrolytic carbon is due to the porous graphene sheets and the high surface area of pyrolytic carbon. The annealing process dramatically reduced gaps between individual graphene sheets and also improved the electrical contacts between graphene sheets around the fibers. At the same time, the porous structure of graphene allows the lithium ion to penetrate into pyrolytic carbon.

### Conclusion

In summary, we have successfully created flexible graphene-coated pyrolytic carbon anode materials by fusing graphene sheet by annealing onto cotton fibers, thus creating graphene-coated cotton, or graphene/cotton composites, for the first time. The novel graphene-coated pyrolytic carbon materials and their excellent electrical properties suggest many potential applications, especially as anodes in lithium batteries. This work is continuing. We believe that this facile, potentially low-cost method can have much broader applications.

References, each of which is incorporated by reference:

[1] K. S. Novoselov, A. K. Geim, S. V. Morozov, D. Jiang, Y. Zhang, S. V. Dubonos, I. V. Grigorieva, and A. A. Firsov. Science, 2004, 306.

[2] Y. B. Zhang, Y. W. Tan, H. L. Stormer and P. Kim, Nature, 2005, 438, 201.

[3] K. S. Novoselov, Nature, 2005, 438, 197.

[4] Y. Hernandez and V. Nicolosi, Nature Nanotech., 2008, 3. 563.

[5] S. S Li, K. H Tu, C. C. Lin, C. W. Chen and M. Chhowalla. ACS Nano, 2010 4, 3169,

[6] H. W. Kim, A. A. Abdala and C. W. Macosko, Macromolecules, 2010, 43, 6515,

[7] J. Q. Liu, L. Tao, W. R. Yang, D. Li, C. Boyer, R. Wuhrer, F. Bract and T. P. Davis, Langmuir, 2010, 26, 10068,

[8] Q. Li, Z. J. Li, M. Chen and Y. Fang, Nano Lett., 2009, 9, 2129,

[9] D. L Son, T. W. Kim, J. H. Shim, J. H. Jung, D. U. Lee, J. M. Lee, W. Park and W. K. Choi Nano. Lett., 2010, 10, 2441,

[10] J. Patil and S. Mann. Adv. Mater, 2009, 21, 2180.

[11] Q. L Bao, H. Zhang, J. X. Yang, S. Wang, D. Y. Tang, R. Jose, S. Ramakrishna, C. T. Lim and K. P. Loh, Adv. Funct. Mater, 2010, 20, 782,

[12] S. M. Pack, E. J. Yoo and I. Honma, Nano Lett., 2009, 9, 72.

[13] E. J. Yoo, J. Kim, E. Hosono, H. S. Zhou, T. Kudo and I. Honma Nano Lett., 2008, 8, 2277.

[14] H. I. Wang, L. F. Cui, Y. Yang, H. S. Casalongue, J. T. Robinson, Y. Liang, Y. Cui, and H. J. Dai. J. Am. Chem. Soc., 2010, 132, 13978.

[15] L. Hu, M. Pasta, F. La Mantia, L.-F. Cui, S. Jeong, H. D. Deshazer, J. W. Choi, S. M. Han, Y. Cui, Nano Lett., 2010, 10, 708.

[16] D. T. Schoen, A. P. Schoen, L. Hu, H. S. Kim, S. C. Heilshorn, Y. Cui, Nano Lett., 2010, 10, 3628.

[17] Q. Su, S. P. Pang, V. Alijani, C. Li, X. L. Feng, K. Mullen, Adv. Mater 2009, 31, 21.

[18] M. Zhang, R. Parajuli, W. Cheung, R. Brukh, H. X. He, Small, 2010, 6, 1100.

[19] L. W. Ji and X. W Zhang, Energy Environ. Sci., 2010, 3, 124.

[20] Y. Xu, H. Bai, G. Lu, G. Shi, J. Am. Chem. Soc. 2008, 130, 5856.

[21] C. Ehli, G. M. A. Rahman, N. Jux, D. Balbinot, D. M. Guldi, F. Paolucci, M. Marcaccio, D. Paolucci, M. Melle-Franco, F. Zerbetto, S. Campidelli, M. Prato, J. Am. Chem. Soc. 2006, 128, 11222.

[22] C. Y Wang, D. Li, C. O. Too and G. G. Wallace. Chem. Mater., 2009, 21, 2604.

[23] S. H. Ng, J. Wang, D. Wexler, K. Konstantinov, Z. P. Guo and H. K. Liu, Angew. Chem., Int. Ed., 2006, 45, 6896.

[24] Y. S. Hu, R. Demir-Cakan, M. M. Titirici, J. O. Muller, R. Schlogl, M. Antonietti and J. Maier, Angew. Chem., Int. Ed., 2008, 47, 1645.

[25] G. X. Wang, J. H. Ahn, J. Yao, S. Bewlay and H. K. Liu, Electrochem. Commun., 2004, 6, 689.

[26] T. Bhardwaj, A. Antic, B. Pavan, V. Barone and B. D. Fahlman, J. Am. Chem. Soc., 2010, 132, 12556

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. In an embodiment, the term “about” can include traditional rounding according to significant figures of the numerical value. In addition, the phrase “about ‘x’ to ‘y’” includes “about ‘x’ to about ‘y’”.

Many variations and modifications may be made to the above-described embodiments. All such modifications and variations are intended to be included herein within the scope of this disclosure and protected by the following claims.

At least the following is claimed:

1. A structure comprising:
a graphene-coated pyrolytic carbon (GCPC) structure.

2. The structure of claim 1, wherein GCPC structure includes a graphene-coated pyrolytic carbon layer around a fiber or a fabric.

3. The structure of claim 2, wherein the fiber or a fabric is a cotton fiber or fabric.

4. The structure of claim 2, wherein the graphene-coated pyrolytic carbon layer has a thickness of about 0.3 nanometers to 1 micrometer.

5. The structure of claim 2, wherein the graphene-coated pyrolytic carbon layer covers the entire fiber or a fabric.

6. A method of making a structure, comprising:
disposing a fiber or a fabric into a graphene/pyrene derivative suspension to coat the fiber or the fabric; and
annealing the coated fabric, wherein a graphene-coated pyrolytic carbon layer is formed around the fiber or fabric.

7. The method of claim 6, wherein the layer is a graphene skin on a pyrolytic carbon scaffold.

8. The method of claim 6, wherein the fiber or fabric is a cotton fiber or fabric.

9. The method of claim 6, wherein the graphene-coated pyrolytic carbon layer has a thickness of about 0.3 nanometers to 1 micrometer.

10. The method of claim 6, wherein the graphene-coated pyrolytic carbon layer covers the entire fiber or a fabric.

11. A structure formed by the process of claim 6.

12. A device, comprising a graphene-coated pyrolytic carbon (GCPC) structure.

13. The device of claim 12, wherein the device is included in an anode, a lithium battery, a flexible electronic device, an anti-static material, an electromagnetic shield, an electrode, a heating element in a textile and in apparel, a sensor, a radio-interference prevention shield, a wearable electronic device, a parabolic antenna reflecting materials, a catalyst, or a biomedical implant.

14. The device of claim 12, wherein GCPC structure includes a graphene-coated pyrolytic carbon layer around a fiber or a fabric.

15. The device of claim 12, wherein the fiber or a fabric is a cotton fiber or fabric.

16. The device of claim 12, wherein the graphene-coated pyrolytic carbon layer has a thickness of about 0.3 nanometers to 1 micron.

17. The device of claim 12, wherein the graphene-coated pyrolytic carbon layer covers the entire fiber or a fabric.
